(19) United States
(12) Patent Application Publication
(10) Pub. No.: US 2026/0052924 A1
(43) Pub. Date: Feb. 19, 2026

(54) HIGH ASPECT RATIO ETCH WITH A NON-UNIFORM METAL OR METALLOID CONTAINING MASK

(71) Applicant: Lam Research Corporation, Fremont, CA (US)

(72) Inventors: Gregory Clinton VEBER, Oakland, CA (US); Ming-Yuan CHUANG, San Jose, CA (US); Ragesh PUTHENKOVILAKAM, Portland, OR (US); Kapu Sirish REDDY, Portland, OR (US); Sonal BHADAURIYA, BEAVERTON, OR (US); Yongsik YU, Northridge, CA (US); Amit MUKHOPADHYAY, Fremont, CA (US); Qing XU, Fremont, CA (US); Merrett WONG, Palo Alto, CA (US)

(21) Appl. No.: 19/105,208

(22) PCT Filed: Aug. 22, 2023
(86) PCT No.: PCT/US2023/030867

§ 371 Date: Feb. 20, 2025

Related U.S. Application Data
(60) Provisional application No. 63/400,828, filed on Aug. 25, 2022.

(51) Int. Cl. H01L 21/311

(52) U.S. Cl. CPC H01L 21/31144; H01L 21/31116

(57) ABSTRACT

A method for etching features in a stack is provided. A non-uniform metal or metalloid containing mask is formed over the stack. The stack is etched through the non-uniform metal or metalloid containing mask, wherein the etching sputters metal or metalloid in the non-uniform metal or metalloid containing mask and the sputtered metal or metalloid physically redeposits on sidewalls of features etched in the stack as a sputtered metal or metalloid containing passivation layer.

### CROSS-REFERENCE TO RELATED APPLICATION

This application claims the benefit of priority of U.S. Application No. 63/400,828, filed Aug. 25, 2022, which is incorporated herein by reference for all purposes.

### BACKGROUND

The disclosure relates to a method of forming semiconductor devices on a semiconductor wafer.

In forming semiconductor devices, etch layers may be etched to form memory holes or lines or other semiconductor features. Some semiconductor devices may be formed by etching a single stack of silicon dioxide also known as silicon oxide (SiO₂), for example, to form a capacitor in dynamic access random memory (DRAM). Other semiconductor devices may be formed by etching stacks of bilayers of alternating silicon dioxide (oxide) and silicon nitride (nitride) (ONON), or alternating silicon dioxide and polysilicon (OPOP). Other stacks of alternating layers may be etched. Some of the stacks of alternating layers may have one of the layers of the alternating layers that is silicon oxide. Some alternating layers may be alternating trilayers. Such stacks may be used in memory applications and three dimensional “not and” gates (3D NAND). These stacks tend to require relatively high aspect ratio (HAR) etching of the dielectrics. For high aspect ratio etches, examples of desired etch characteristics are high etch selectivity to the mask (such as an amorphous carbon mask), low sidewall etching with straight profiles, and high etch rate at the etch front. Some high aspect ratio etches result in tapered features that are much wider at the top than the bottom. Such features may increase device failure or limit device density, device performance, and device depth.

In some etch processes of an OPOP stack with an amorphous carbon mask, during the etch, a metal containing passivant is used during the etch process. The metal containing passivant may be provided during the etch process so that passivation and etching occur simultaneously or there may be alternating steps of passivation and etching. It has been found that when a tungsten (W) passivation is used, the tungsten selectively deposits on the polysilicon with respect to the silicon oxide so that there is less passivation on the silicon oxide than on the polysilicon. The reduced passivation of silicon oxide results in increased defects, such as increased CD and notching. The weakest or thinnest deposition dictates the ability of the passivation layer to protect the underlying material. For example, once the thinner deposition on the oxide degrades during additional etching, the oxide can begin to be etched even if the Si still has tungsten passivation. The etching of the oxide causes the CD to increase as well as additional defect formation such as notching, keyholes, etc. Non-uniform passivation may also cause profile twisting, kink, and ion sided bowing.

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack is provided. A non-uniform metal or metalloid containing mask is formed over the stack. The stack is etched through the non-uniform metal or metalloid containing mask, wherein the etching sputters metal or metalloid in the non-uniform metal or metalloid containing mask and the sputtered metal or metalloid physically redeposits on sidewalls of features etched in the stack as a sputtered metal or metalloid containing passivation layer.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of processes used in some embodiments.

FIGS. 2A-E are schematic cross-sectional views of a stack processed according to some embodiments.

FIG. 3A is a schematic cross-sectional view of a stack in another embodiment.

FIG. 3B is a schematic cross-sectional view of a stack in another embodiment.

FIG. 4 is a schematic view of an etch chamber that may be used in some embodiments.

FIG. 5 is a schematic view of a computer system that may be used in practicing some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Dry development of high aspect ratio contacts requires strict control of the tapering angle of the sidewall. Various methods try to limit lateral critical dimension (CD) differences between the top and bottom parts of the etched structures. With the recent development of 3D NAND memory having thicker structures with an increased number of ONON or OPOP bilayers, the demand for tight control of top and bottom geometries is especially significant. In case the profile (difference between the top and bottom CDs) increases, subsequent steps of device manufacturing will be at risk that will impact device performance. In the current technology, reactive ion etching of high aspect ratio structures relies on sidewall deposition to protect against CD lateral erosion. A delicate balance between etching and sidewall deposition is especially difficult to maintain for high aspect ratio features. As a result, high aspect ratio dry development is limited to thinner structures and requires significant complex development to enable a thick stack to be etched.

In addition, as features are etched, etching near the tops of features may have different characteristics than etching near the bottoms of features. For example, when the features are shallow, less sidewall passivation may be needed. As the features are etched deeper, more sidewall passivation may be needed near the top sidewalls of the features.

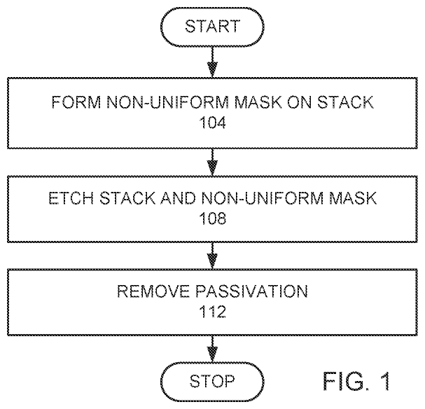

Some embodiments described herein provide deeper high aspect ratio features etched in a stack, where widths of the features near the top of the features are about equal to widths of the features near the bottoms of the features. To facilitate understanding, FIG. 1 is a high level flow chart that may be used in some embodiments. A non-uniform metal or metalloid containing mask is deposited on a stack (step 104). In some embodiments, a plasma enhanced physical vapor deposition (PECVD) is used to deposit a metal containing dielectric film that may be used as a first mask layer. A method of using PECVD to deposit a tungsten carbide film is described in U.S. Pat. No. 9,875,890, entitled “Deposition of Metal Dielectric Film for Hardmask,” issued on Jan. 23, 2018, which is incorporated by reference for all purposes and may be used in some embodiments. In some embodiments, the deposited tungsten carbide film is patterned to form a mask. In some embodiments, a metal and metalloid free carbon mask is deposited on the first mask layer forming a second mask layer.

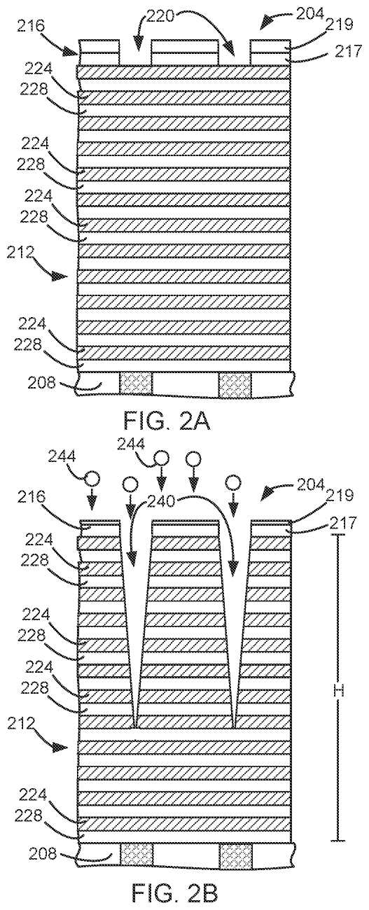

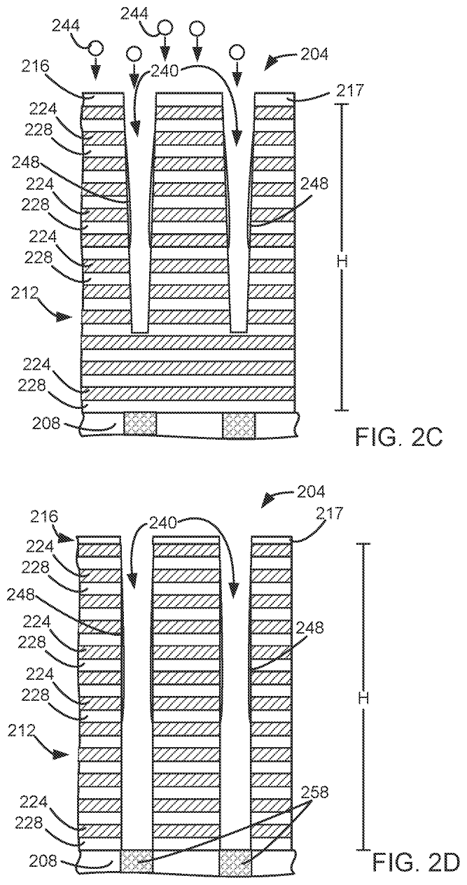

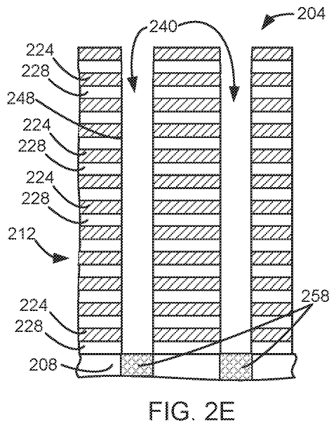

FIG. 2A is a schematic cross-sectional view of a stack 204 that may be etched in some embodiments. In some embodiments, the stack 204 comprises a substrate 208 under a plurality of bilayers 212 disposed below a patterned non-uniform mask 216. In some embodiments, the patterned non-uniform mask 216 comprises a first mask layer 217 and a second mask layer 219. In some embodiments, the first mask layer 217 is a metal or metalloid containing layer, and the second mask layer 219 is metal and metalloid free. In some embodiments, the first mask layer 217 is an amorphous carbon mask doped with tungsten and the second mask layer 219 is pure amorphous carbon. In some embodiments, one or more layers may be disposed between the substrate 208 and the plurality of bilayers 212 and/or the plurality of bilayers 212 and the patterned non-uniform mask 216. In some embodiments, the patterned non-uniform mask pattern 216 provides mask features 220 for high aspect ratio contacts. In some embodiments, the mask features 220 are formed before the stack 204 is placed in the etch chamber. In other embodiments, the mask features 220 are formed while the stack 204 is in the etch chamber. In some embodiments, each bilayer 212 includes a layer of silicon oxide 224 and a layer of silicon nitride 228.

The stack and non-uniform mask are etched (step 108). In some embodiments, an etching gas is provided. In some embodiments, the etching gas is a metal and metalloid free gas. In some embodiments, RF power is provided to transform the etching gas into a plasma with etching ions. A voltage is applied to accelerate etching ions from the plasma to the stack. In some embodiments, metal and metalloid free etching ions are provided from an ion source and accelerated to the stack. The etching ions etch the stack. The etching of the stack may comprise at least one of a chemical etching and physical sputtering of the stack.

FIG. 2B is a schematic cross-sectional view of a stack 204 during the etching to form partially etched features 240. Etching ions 244 are accelerated towards the stack 204. The etching ions 244 etch the stack 204 forming the partially etched features 240 and etch some of the second mask layer 219 of the non-uniform mask 216. In the embodiment shown in FIG. 2B, the partially etched features 240 are significantly tapered since the second mask layer 219 does not provide metal or metalloid passivation.

The etching of the stack 204 is continued. The second mask layer 219 of the non-uniform mask 216 is completely etched away and the first mask layer 217 of the non-uniform mask 216 is exposed to etching ions 244. FIG. 2C is a schematic cross-sectional view of a stack 204 during the further etching of partially etched features 240. Etching ions 244 are accelerated towards the stack 204. The etching ions 244 etch the stack 204 further etch the partially etched features 240 and sputter some of the first mask layer 217 of the non-uniform mask 216. In some embodiments, the etching ions 244 provide two separate processes for depositing metal or metalloid passivation on the sidewalls of the features 240. In one process, the etching ions 244 sputter metal or metalloid atoms from the non-uniform mask 216 into the plasma creating metal or metalloid species from the first mask layer 217. The metal or metalloid species in the plasma are chemically deposited on the sidewalls of the features 240. In a second process, metal or metalloid is sputtered from the first mask layer 217 of the non-uniform mask 216 and is redeposited on the sidewalls of the partially etched features 240. In some embodiments, a sputtered metal or metalloid containing passivation layer 248 is formed by both the chemical deposition of metal or metalloid passivation and the physical sputtering of metal or metalloid. This physical sputtering mechanism overcomes the reduced metal or metalloid containing deposition that can be obtained from a chemical or ion assisted deposition process specifically on silicon oxide, allowing for a more uniform passivation layer.

In some embodiments, the etching of the stack is continued until the etching of the stack is completed. FIG. 2D is a schematic cross-sectional view of a stack 204 after the etching of the stack 204 is completed. In some embodiments, the features 240 are etched the entire depth of the stack 204 so that the features 240 reach electrically conductive contacts 258 in the substrate 208. A sputtered metal or metalloid containing passivation layer 248 protects the sidewalls of the features 240 and additionally can provide an increase in vertical etch rate thus reducing overall process times.

In some embodiments, the metal or metalloid containing passivation layer 248 is removed (step 112). In some embodiments, a wet process is used to remove the sputtered metal or metalloid containing passivation layer 248. In some embodiments, a dry process is used. FIG. 2E is a schematic cross-sectional view of a stack 204 after the sputtered metal or metalloid containing passivation layer 248, shown in FIG. 2D, has been removed. In some embodiments, the first mask layer 217 of the non-uniform mask 216, shown in FIG. 2D, is removed in the same process used to remove the sputtered metal or metalloid containing passivation layer. In some embodiments, the non-uniform mask is removed using a different process used to remove the sputtered metal or metalloid containing passivation layer.

One major issue during high aspect ratio (HAR) etch is CD scaling, specifically as desired features become vertically scaled there is a simultaneous push to keep lateral feature size constant. In practice, this can be very difficult to achieve and many of the current technologies have tradeoffs. In some embodiments, a tungsten doped carbon hard mask is utilized not only to protect the stack from undesired etch but also to provide robust tungsten species that deposit on the sidewall of the etch feature and protect from additional lateral etch. This robust tungsten containing passivation on the sidewall of the feature allows for CD control and prevents other defect formation, such as notching. Additionally, some embodiments allow for both chemical deposition from tungsten species, but also the direct physical sputtering of tungsten doped carbon, thus providing more uniform passivation at the top of the feature. The tungsten in the first mask layer 217 provides tungsten for the tungsten sidewall passivation.

In some embodiments, the tungsten passivation is not needed at the beginning of the etch of the features 240. The second mask layer 219 is tungsten free so that there is no metal or metalloid passivation. The etch without metal or metalloid passivation at the beginning of the etch allows for a faster etch. At the beginning of the etch when the feature has a low aspect ratio, robust metal/metalloid containing material can hinder the vertical etch rate due to excessive deposition at the etch front. In addition, too much deposition early on can lead to constricted CDs at the top of the features. This constriction could lead to ion scattering in the feature, causing a double bow formation and increased pillar twisting.

By providing a non-uniform mask, with a first mask layer having a tungsten containing dopant and a second mask layer is metal and metalloid free, the non-uniformity of the mask may be tuned or tailored to match a non-uniformity of the process of etching the features. The non-uniformity of the process of etching features may be caused by different etch conditions at different etch depths. In addition, at different etch depths, different etch goals are pursued. For example, at the beginning of the etch, the focus of the etch is to etch downward as quickly as possible even though the etch process forms tapered features, as shown in FIG. 2B. Near the end of the etch process, the speed of the etch downward is slowed, the sidewalls near the top of the features are protected by metal or metalloid containing sidewall passivation, and the taper is removed. Therefore, in some embodiments, the non-uniform mask has a non-uniformity that is tuned to provide a desired non-uniform etch process.

Some embodiments have been found to provide a tuned passivation that is better at preventing additional lateral etch rate and defect formation, such as notching, by depositing a tuned tungsten containing species on SiO₂ that is not limited to previous deposition quality/thickness of tungsten on SiO₂ provided in the previously used processes. Some embodiments provide improvements in several ways because the tungsten needed to generate the protective passivation material comes from the mask material itself. The improvement provided in some embodiments is from the passivation deposition mechanism. The sputtering of the tungsten from the non-uniform mask causes molecular tungsten species to be added as a reactant gas but also causes physical sputtering of tungsten doped carbon mask material to redeposit on sidewalls. Therefore, both a chemically assisted deposition process (from tungsten by-product formation) and a physical sputtering process (from carbon doped with tungsten) are occurring, the combination of which allows for very uniform deposition across different materials in the etch feature. Overall, this significantly helps protect the top area in the feature from lateral etch and defect formation (notching) both on the bare Si and SiO2 materials.

Some embodiments may be used on an Oxide/Nitride (ONON) multilayer stack to form features, such as contact holes or trenches, in making a 3D NAND memory device. Some embodiments may be used for dynamic random access memory (DRAM) Capacitor etching. Some embodiments may be used to etch silicon oxide and polysilicon bilayers (OPOP). Some embodiments provide an etch depth of greater than 1 micron. In some embodiments, the etch depth is greater than 10 microns.

An advantage of some embodiments is the ability of a device manufacturer to be able to have a more precise control of the profile of a high aspect feature. Various embodiments enable increasing the bottom CD for very high aspect features. Various embodiments enable the next generations of devices that rely on deeper structures with higher aspect ratios. Various embodiments reduce the cost of device manufacturing by reducing the number of steps for the development of high aspect ratio contacts. Various embodiments reduce the variation of the width of the features along the depth of the features so that the difference between widths at any two points along the depth of the features 240.

In some embodiments, the non-uniform mask may have more than two mask layers where at least one mask layer is a metal or metalloid containing mask. For example, in some embodiments, the non-uniform mask may comprise a first mask layer of silicon oxide or carbon, a second mask layer of a metal or metalloid containing carbon based material, and a third mask layer of a metal and metalloid free carbon based material. In some embodiments, the first mask layer is a metal and metalloid free layer and the second mask layer is a metal or metalloid containing layer. In some embodiments, the non-uniform mask comprises at least one layer of at least one of carbon, silicon oxide, and tetraethoxysilane (TEOS) in addition to at least one layer of a metal or metalloid containing mask layer.

In some embodiments, the stack may be etched using more than one etch step. In some embodiments, the non-uniform mask is tailored to match different etch steps. For example, a first etch step of an ONON stack may be a fast shallow vertical etch. So, a top layer of the non-uniform mask may be metal and metalloid free. A second etch step may use a more aggressive etch to open the bottom of deep features. So, the lower layer of the non-uniform mask may have metal or metalloid containing dopant to provide metal or metalloid containing sidewall passivation to protect the sidewalls of the tops of the features during the more aggressive etch. In some embodiments, different mask layers of the non-uniform mask may have different metal or metalloid dopants.

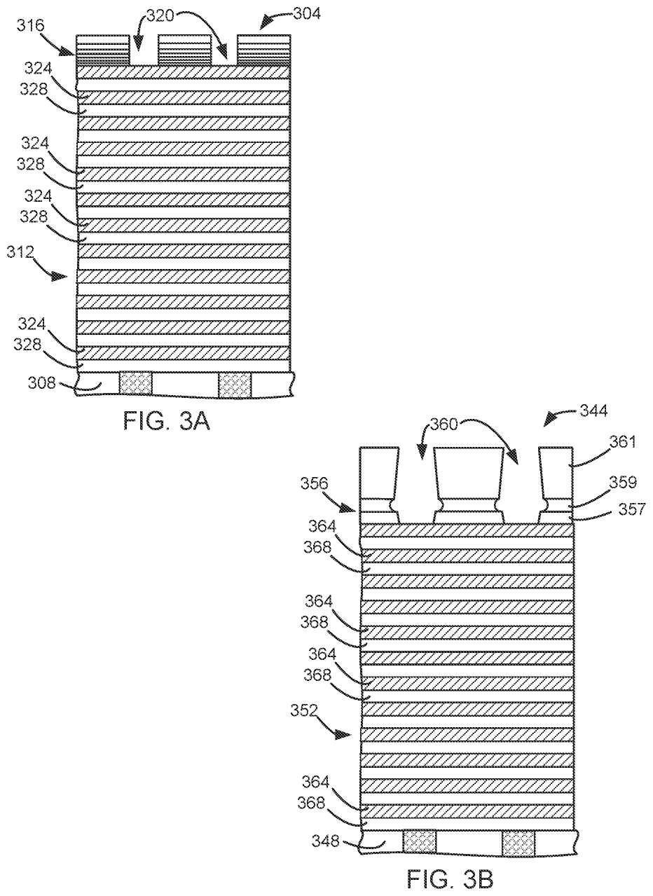

FIG. 3A is a schematic cross-sectional view of a stack 304 that may be etched in some embodiments. In some embodiments, the stack 304 comprises a substrate 308 under a plurality of bilayers 312 disposed below a patterned non-uniform mask 316. In some embodiments, the patterned non-uniform mask 316 comprises a mask doped with metal or metalloid dopants where the concentration of the metal or metalloid dopant forms a gradient in the direction from the top of the non-uniform mask 316 to the bottom of the mask. In this example, the metal or metalloid dopant concentration increases going from the top of the non-uniform mask 316 to the bottom of the non-uniform mask 316, as indicated by the increased shading concentration. In some embodiments, the patterned non-uniform mask pattern provides mask features 320 for high aspect ratio contacts. In some embodiments, the mask features 320 are formed before the stack 304 is placed in the etch chamber. In other embodiments, the mask features 320 are formed while the stack 304 is in the etch chamber. In some embodiments, each bilayer 312 includes a layer of silicon oxide 324 and a layer of silicon nitride 328.

In etching the stack 304, the low concentration of metal or metalloid dopant in the non-uniform mask 316 may allow for an initial etch that provides a faster etch with a lower amount of metal or metalloid passivation. Since the concentration of metal or metalloid dopant increases from the top to the bottom of the mask, as the etch proceeds, the etching process may slow, and the metal or metalloid passivation may increase. In some embodiments, if a stack needs more passivation as features are etched deeper into a stack, then the mask may have a gradient with a higher concentration of metal or metalloid passivant near the bottom of the non-uniform mask so that the higher concentration of metal or metalloid passivant would be exposed to the plasma only when more of the mask is removed when the features are etched deeper.

In other embodiments, the non-uniform mask may have a gradient with the highest concentration of metal or metalloid dopant near the top of the non-uniform mask. In other embodiments, the non-uniform mask may have a gradient with the highest concentration of metal or metalloid dopant somewhere between the top and bottom of the non-uniform mask. In some embodiments, the non-uniform mask may be at least two layers, where at least one layer has a metal or metalloid dopant gradient. In some embodiments, the metal or metalloid dopant makes up 1% to 50% by weight of the mask material of a mask layer.

FIG. 3B is a schematic cross-sectional view of a stack 304 that may be etched in some embodiments. In some embodiments, the stack 344 comprises a substrate 348 under a plurality of bilayers 352 disposed below a patterned non-uniform mask 356. In some embodiments, the patterned non-uniform mask 356 comprises a first mask layer 357, a second mask layer 359, and a third mask layer 361. In some embodiments, each bilayer 352 includes a layer of silicon oxide 364 and a layer of silicon nitride 368. At least one of the first mask layer 357, the second mask layer 359, and the third mask layer 361 contains metal or metalloid. In some embodiments, the profile of the non-uniform mask 356 is non-uniform but instead is tuned to the desired etch results. For example, the first mask layer 357 may be TEOS, the second mask layer 359 may be a metal or metalloid doped carbon layer, and the third mask layer 361 may be an amorphous carbon layer without metal or metalloid dopant. The first mask layer 357 is tapered in the downward direction. The third mask layer 361 is enlarged in the downward direction. As a result, the second mask layer 359 has the largest CD of the mask features 360 of the non-uniform mask 356. As a result, the non-uniform profile of the mask features 360 may provide further control of the metal or metalloid passivation and another knob for controlling the etch process.

In some embodiments, the stack may be a single silicon containing layer, such as a single layer of silicon oxide, silicon nitride, or silicon. In some embodiments, the stack may comprise a single layer or multiple layers of other silicon containing materials.

In some embodiments, for etching a stack with a silicon layer, the non-uniform mask may further comprise oxygen. In some embodiments, for etching a silicon oxide stack, the non-uniform mask may further comprise silicon. Some embodiments may have other materials in addition to the metal or metalloid dopant. In some embodiments, the metal in the metal or metalloid containing mask is at least one of tungsten, molybdenum, ruthenium, tantalum, titanium, platinum, and aluminum. In other embodiments, the metalloid is boron. In some embodiments, the etching gas is metal and metalloid free, since metal and metalloid species are provided by sputtering of the metal or metalloid containing mask.

Some embodiments provide rational design novel mask stacks specifically tailored to impart benefits to the downstream in a high aspect ratio (HAR) etch process, specifically geared toward improving etch rates and etch feature profile (i.e. bow CD, bottom CD, taper, twisting, defect formation, etc.) which would otherwise be very difficult to achieve from tuning the HAR process alone.

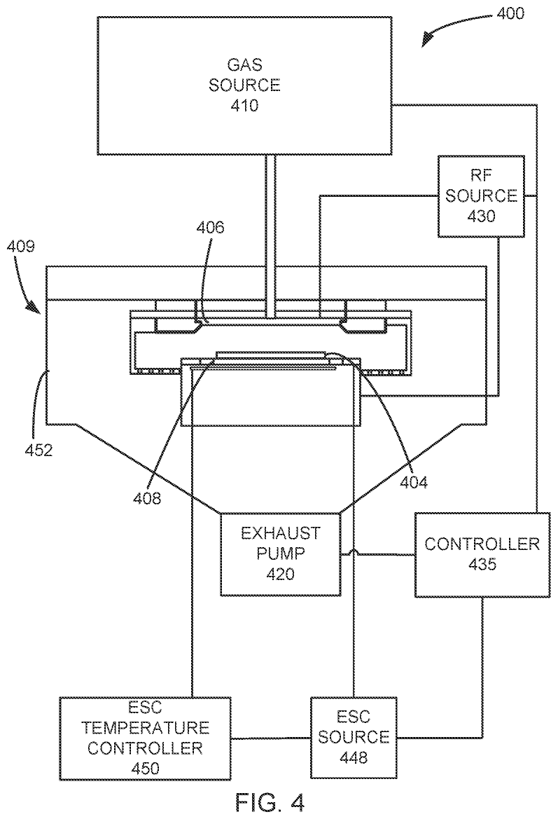

FIG. 4 is a schematic view of an etch reactor system 400 that may be used in some embodiments. In some embodiments, an etch reactor system 400 comprises a gas distribution plate 406 providing a gas inlet and an electrostatic chuck (ESC) 408, within an etch chamber 409, enclosed by a chamber wall 452. Within the etch chamber 409, a stack 404 is positioned over the ESC 408. The ESC 408 may provide a bias from the ESC source 448. An etch gas source 410 is connected to the etch chamber 409 through the gas distribution plate 406. An ESC temperature controller 450 is connected to the ESC 408. A radio frequency (RF) source 430 provides RF power to a lower electrode and/or an upper electrode, which in this embodiment are the ESC 408 and the gas distribution plate 406, respectively. In some embodiments, 400 kilohertz (kHz), 60 megahertz (MHz), and optionally, 2 MHz, 27 MHz power sources make up the RF source 430 and the ESC source 448. In some embodiments, the upper electrode is grounded. In some embodiments, one generator is provided for each frequency. In some embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 435 is controllably connected to the RF source 430, the ESC source 448, an exhaust pump 420, and the etch gas source 410. An example of such an etch chamber is the Flex™ etch system manufactured by Lam Research Corporation of Fremont, CA. The process chamber can be a CCP (capacitively coupled plasma) reactor or an ICP (inductively coupled plasma) reactor.

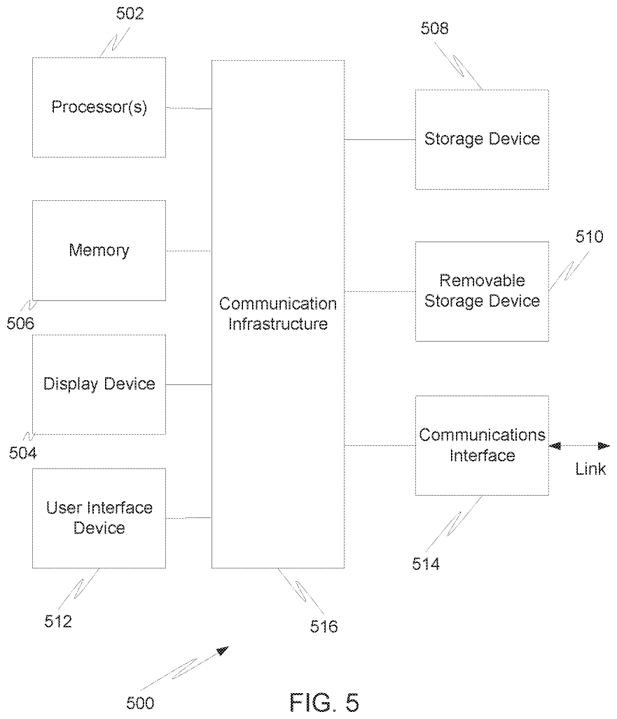

FIG. 5 is a high level block diagram showing a computer system 500, which is suitable for implementing the controller 435 used in embodiments. The computer system 500 may have many physical forms ranging from an integrated circuit, a printed circuit board, and a small handheld device up to a huge supercomputer. The computer system 500 includes one or more processors 502 and further can include an electronic display device 504 (for displaying graphics, text, and other data), a main memory 506 (e.g., random access memory (RAM)), storage device 508 (e.g., hard disk drive), removable storage device 510 (e.g., optical disk drive), user interface devices 512 (e.g., keyboards, touch screens, keypads, mice or other pointing devices, etc.), and a communications interface 514 (e.g., wireless network interface). The communications interface 514 allows software and data to be transferred between the computer system 500 and external devices via a link. The system may also include a communications infrastructure 516 (e.g., a communications bus, cross-over bar, or network) to which the aforementioned devices/modules are connected.

Information transferred via communications interface 514 may be in the form of signals such as electronic, electromagnetic, optical, or other signals capable of being received by communications interface 514, via a communications link that carries signals and may be implemented using wire or cable, fiber optics, a phone line, a cellular phone link, a radio frequency link, and/or other communications channels. With such a communications interface 514, it is contemplated that the one or more processors 502 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that is executed by a computer using an interpreter. Computer readable media may also be computer code transmitted by a computer data signal embodied in a carrier wave and representing a sequence of instructions that are executable by a processor.

In some embodiments, in-situ monitoring of the plasma during either the opening of the mask or the etching of the stack may be used to adjust an etch or opening recipe in real time. The monitoring of the plasma may be used to detect and measure the concentration of a species, such as a metal or metalloid in the plasma or maybe used to detect and measure relative concentrations of two or more different species. The detected concentrations of measured species may be used to modify the recipe in real time in order to provide a desired opening or etch.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack, comprising:
a) forming a non-uniform metal or metalloid containing mask over the stack; and
b) etching the stack through the non-uniform metal or metalloid containing mask, wherein the etching sputters metal or metalloid in the non-uniform metal or metalloid containing mask and the sputtered metal or metalloid physically redeposits on sidewalls of features etched in the stack as a sputtered metal or metalloid containing passivation layer.

2. The method, as recited in claim 1, wherein the etching the stack comprises:
providing metal and metalloid free etching ions; and
accelerating the etching ions to the stack, wherein the etching ions etch features in the stack and sputter metal or metalloid from the metal or metalloid containing mask.

3. The method, as recited in claim 2, wherein the metal or metalloid containing passivation layer provides metal or metalloid species.

4. The method, as recited in claim 3, wherein the metal or metalloid species chemically deposits on sidewalls of the features in addition to the sputtered metal or metalloid physically redeposited on sidewalls of features.

5. The method as recited in claim 1, wherein the metal or metalloid is at least one of tungsten, molybdenum, ruthenium, tantalum, titanium, platinum, aluminum, and boron.

6. The method, as recited in claim 1, wherein the stack is a silicon containing stack.

7. The method, as recited in claim 1, wherein the stack is a silicon oxide containing stack.

8. The method, as recited in claim 1, wherein the stack is a plurality of alternating layers, wherein at least one layer of the plurality of alternating layers is a silicon oxide containing layer.

9. The method, as recited in claim 1, further comprising removing the sputtered metal or metalloid containing passivation layer.

10. The method, as recited in claim 1, wherein the forming of a non-uniform metal or metalloid containing mask over the stack comprises forming a metal or metalloid containing mask with a gradient that changes a concentration of metal or metalloid from a top of the non-uniform metal or metalloid containing mask to a bottom of the non-uniform metal or metalloid containing mask.

11. The method, as recited in claim 1, wherein the forming a non-uniform metal or metalloid containing mask over the stack comprises forming a metal or metalloid containing mask with a first mask layer and a second mask layer, wherein the first mask layer has at least a first concentration of metal or metalloid and the second mask layer has no more than a second concentration of metal or metalloid, wherein the first concentration is greater than the second concentration.

12. The method, as recited in claim 11, wherein the second mask layer is between the first mask layer and the stack.

13. The method, as recited in claim 11, wherein the first mask layer is between the second mask layer and the stack.

14. The method, as recited in claim 11, wherein the second mask layer is metal or metalloid free.

15. The method, as recited in claim 1, further comprising measuring species in a plasma used for etching and adjusting the etching of the stack according to measured species.

16. The method, as recited in claim 1, wherein a profile of the non-uniform metal or metalloid containing mask is non-uniform.
